(19) United States
(12) Patent Application Publication
(10) Pub. No.: US 2013/0314107 A1
(43) Pub. Date: Nov. 28, 2013

(54) DEVICE AND METHOD FOR DETERMINING A MEASURING CAPACITANCE

(71) Applicant: Martin Mellert, Steinbach (DE)

(72) Inventor: Martin Mellert, Steinbach (DE)

(73) Assignee: VEGA GRIESHABER KG, Wolfach (DE)

(21) Appl. No.: 13/793,477

(22) Filed: Mar. 11, 2013

Related U.S. Application Data
(60) Provisional application No. 61/638,428, filed on Apr. 25, 2012.

(30) Foreign Application Priority Data
Apr. 24, 2012 (EP) 12 165 250.7

(51) Int. Cl. G01R 27/26

(52) U.S. Cl. CPC G01R 27/2605
USPC 324/676

(57) ABSTRACT

A measuring device determines a measuring capacitance (CM), with a clock oscillator, which oscillates in a scanning frequency (f_{A}), a measuring oscillator, which oscillates in a measurement frequency in dependence on a measuring capacitance (C_{M}), and an edge counter, which counts the number of clock oscillations during a given number of measuring oscillations, wherein a circuit is provided for measurement refinement, wherein the circuit for measurement refinement is started by a measuring edge of a last scanned measuring oscillation and stopped by an equally oriented and immediately following edge of a subsequent clock oscillation.

### CROSS REFERENCE TO RELATED APPLICATIONS

This application claims priority to European Ser. No. 12 165 250.7 filed Apr. 24, 2012 and U.S. Ser. No. 61/638,428 filed Apr. 24, 2013, the entire contents of each of which are incorporated fully by reference.

### FIGURE SELECTED FOR PUBLICATION

FIG. 1

### BACKGROUND OF THE INVENTION

1. Field of the Invention

The present invention relates to a measurement device. More particularly, this invention relates to an improved measurement device and a method that determines the measuring capacitance with improved accuracy with a built-in circuit to refine measurement cycles and the synchronization of oscillators.

2. Description of the Related Art

A determination of a measuring capacitance is used, for example, in the area of pressure measurement, where a measuring capacitance changes in dependence on a pressure acting on a measuring membrane.

It is generally known how to determine a measuring capacitance by a frequency measurement of a measurement frequency of a measuring oscillator, which oscillates in dependence on the measuring capacitance. For this purpose, a clock oscillator is provided, which oscillates in a scanning frequency, and the number of clock oscillations during a particular number of measurement oscillations is detected with an edge counter. Knowing the scanning frequency, it is possible to determine from the number of edges counted a period length for the measurement oscillations and, from this, to calculate a frequency of the measurement oscillations. Based on the frequency of the measurement oscillations and knowing the design of the measurement oscillator, it is then possible to detect the magnitude of the measuring capacitance at the particular moment in time and, in the case of a pressure measurement, to draw an inference as to the prevailing pressure in dependence on a configuration of the pressure measuring cell being used.

In general, in the determination of a measured value with sensors by a frequency measurement, the resolution is limited by the scanning frequency of the clock oscillator as well as the length of a measurement. For example, if a resolution of 14 bits is to be achieved with a scanning frequency of 1 MHz, then a measuring time of 1 ms×2¹⁴=16,384 ms is needed.

If the resolution is to be increased, a larger measurement time is required or it is necessary to increase the scanning frequency accordingly.

In order to get reliable measurements, however, it is desirable to not exceed a given measurement time in the measurement equipment. Conventionally, if a resolution is to be achieved increased nevertheless, it is mandatory to increase the scanning frequency. Such an increase of the scanning frequency, however, begins a detrimental increases in power consumption.

A first approach to solve this problem is to increase resolution by taking the measurement signal to a cascade of delay elements, whose output signals, each of them delayed relative to each other, are taken to a cascade of comparators hooked up in parallel with it, which compare the mutually delayed measurement signals with the scanning signal. When each delay element delays the signal supplied to it by, for example, one quarter of the length of the scanning frequency period, the resolution can be increased by 2 bits.

However, the drawback for this approach is that the operation of the delay elements, the comparators, and a register in which the comparison values generated by the comparators are stored, likewise signifies an increased current consumption while measurement errors occur on account of the oscillators oscillating independently of each other.

### ASPECTS AND SUMMARY OF THE INVENTION

According to one aspect of the present invention a measuring device for the determination of a measuring capacitance has a clock oscillator, which oscillates in a scanning frequency, a measuring oscillator, which oscillates in a measurement frequency in dependence on a measuring capacitance, and an edge counter, which counts the number of clock oscillations during a given number of measuring oscillations, wherein a circuit is provided for measurement refinement, which is started by the measuring edge of a last scanned measuring oscillation and stopped by the equally oriented and immediately following edge of a subsequent clock oscillation.

In a particular refinement of the proposed invention, the circuit for measurement refinement is activated only partially, i.e., in particular, at the end of a measurement cycle, and thus the energy consumption of the circuit is immensely reduced. If an overall measurement cycle takes, e.g., around 5 ms, the length of the activation of the circuit for measurement refinement can be reduced by around 80%, i.e., to 1 ms, therefore the energy consumed by the circuit for measurement refinement is similarly immensely reduced.

The present invention also further proposes that the measuring oscillator is started in synchronization with the clock oscillator. When oscillators are oscillating independently of each other, it is not known which state the measurement signal finds itself in at the moment for the first scanning of the measurement signal or for the first edge of the clock signal counted by the edge counter. The first detected edge can thus vary by up to half the length of the scanning frequency period depending on the current oscillation state of the clock oscillator relative to the measuring oscillator.

By synchronizing the starting of the measuring oscillator with that of the clock oscillator, a defined starting situation is achieved, so that the precision of the obtained measurement values is thereby increased.

Preferably, the number of measurement pulse edges during which the number of clock oscillations is determined by the edge counter is controlled by a predetermined measurement time. The measurement time can be, for example, at least 5 ms. The number of measurement pulse edges is then set by means of a circuit with hysteresis so that it is increased by 1 when the measurement time drops below 5 ms and reduced by 1 when the measurement length exceeds 6 ms.

In a further optional and alternative embodiment, the falling measurement edges are detected by the edge counter, so that the measuring oscillator and the clock oscillator can be started in synchronization with a trigger of a falling edge. Thus, the number of falling edges would provide clear information as to the number of oscillations of the clock oscillator and the associated measurement time.

The direct influence of the measuring capacitance on the frequency of the measuring oscillator is preferably arranged in an oscillating circuit which constitutes the measuring oscillator. In this way, it can be guaranteed that a changing of the measuring capacitance has immediate influence on the frequency of the measuring oscillator without any intervening voltage transformation.

In another aspect of the present invention, the circuit for measurement refinement can be outfitted, e.g., with a plurality of series-connected delay elements, to which the measurement signal can be supplied and at whose outputs a measurement signal can be picked off that is delayed relative to each other, with each other being the comparison signal.

The circuit for measurement refinement, moreover, can have a plurality of comparators, to which the clock signal is supplied on the one hand, and one of the comparison signals is supplied on the other hand. Given a number of n delay elements, each delaying the measurement signal is by 1/n of the clock signal, the position of the last falling edge can be determined accurately to 1/n of the length of the clock signal period. The output values of these comparators are preferably written into a register, and are read out after the close of the measurement refinement.

The delay elements for this are preferably configured with an identical delay.

The ultimately achievable measurement signal can be delayed by log2N bits, depending on the number of delay stages and comparators used. For example, by providing four delay stages and comparators one can achieve an increase in the resolution of log₂⁴=2 bits. To accomplish an increase in resolution of 3 bits, one would require n=2³=8 delay elements and comparators.

The delay elements are configured, e.g., as RC elements with a series-connected amplifier.

In another alternative aspect of the present invention a method is provided for the measurement of a measuring capacitance, wherein a clock oscillator oscillates with a scanning frequency and a measuring oscillator with a measuring frequency depending on the measuring capacitance, wherein an edge counter counts the number of clock oscillations during a given number of measurement oscillations and a circuit for measurement refinement is started by a measuring pulse edge of a last scanned measurement oscillation and stopped by an equally oriented edge of an immediately following clock oscillation.

By a starting of the measurement refinement by a measuring pulse edge of a last scanned measurement oscillation and a stopping of the circuit for measurement refinement by an equally oriented edge of an immediately following clock oscillation, the duration of the measurement refinement step is substantially reduced and this likewise reduces the consumption of resources by the measurement refinement.

In order to achieve a further increase in the measurement precision of the invented method, the measuring oscillator is preferably started in synchronization with the clock oscillator. In this way, one can avoid a fluctuation at the start of the measurement, which can be as much as half a clock period.

The number of measurement oscillations is preferably set dependent on a predetermined measurement time. For example, if a measurement time of at least 5 ms, the number of measurement oscillations can be set, for example, such that the number of measurement oscillations is increased by 1 when the measurement time exceeds 5 ms and the number of measurement oscillations is reduced by 1 when the measurement time exceeds 6 ms, for example.

Upon reaching the given number of measuring pulse edges, the measurement is halted with a following, preferably equally oriented measuring edge. Without use of the circuit for measurement refinement, the measurement signal so determined and the measuring capacitance found from this generally deviate from the actual value of the measuring capacitance, since the last counted edge of the clock oscillation of course comes after the last edge of the measurement oscillation.

According to another alternative embodiment of the present invention, a method is provided wherein the measurement signal is repeatedly delayed for the measurement refinement. The delayed measurement signal is compared to the clock signal and the result of this comparison, constituting a portion of the clock signal, is subtracted from the number of clock oscillations found.

The circuit for measurement refinement is preferably started by a falling edge of the measurement signal and stopped by an immediately following edge of the clock signal.

The number of edges so determined can then be reduced by the fraction of a clock signal as determined by the measurement refinement, so that the increased precision is achieved in the determination of the measurement value.

The above and other aspects, features and advantages of the present invention will become apparent from the following description read in conjunction with the accompanying drawings, in which like reference numerals designate the same elements.

### BRIEF DESCRIPTION OF THE DRAWINGS

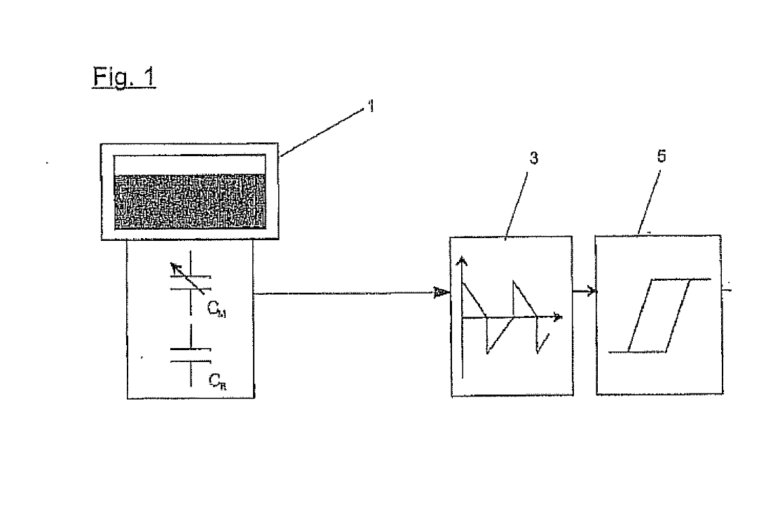

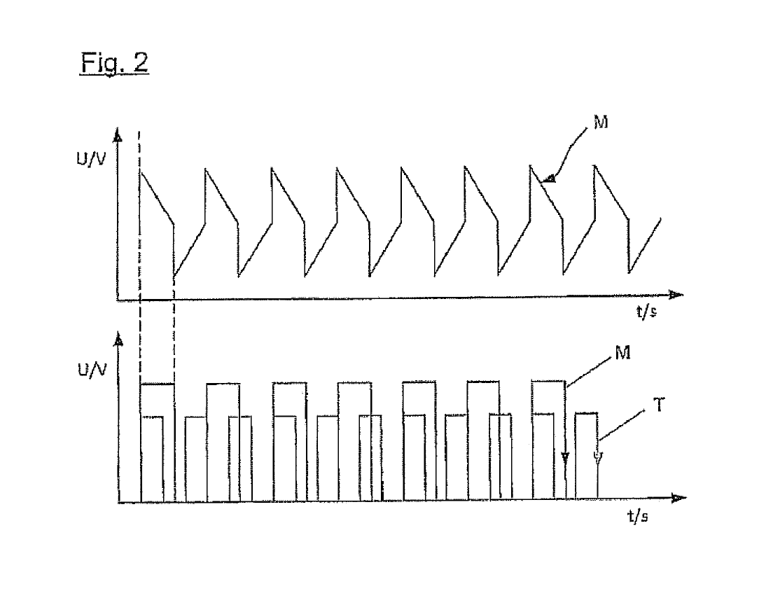

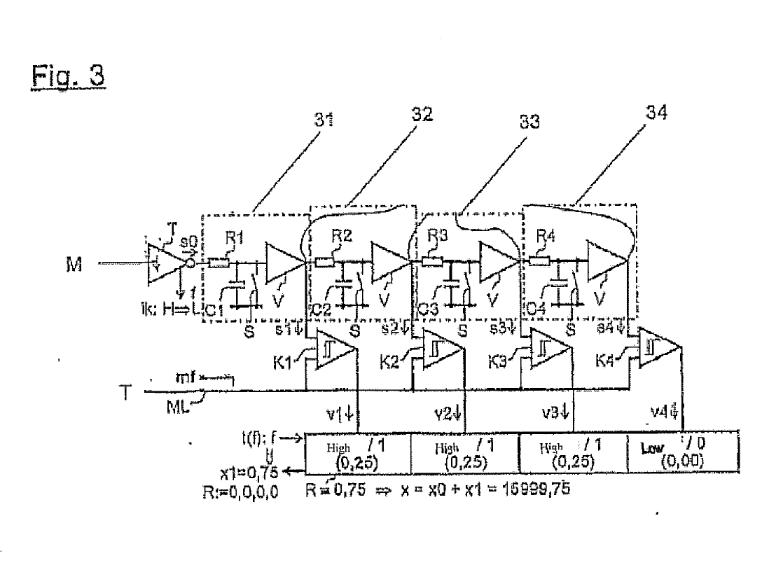

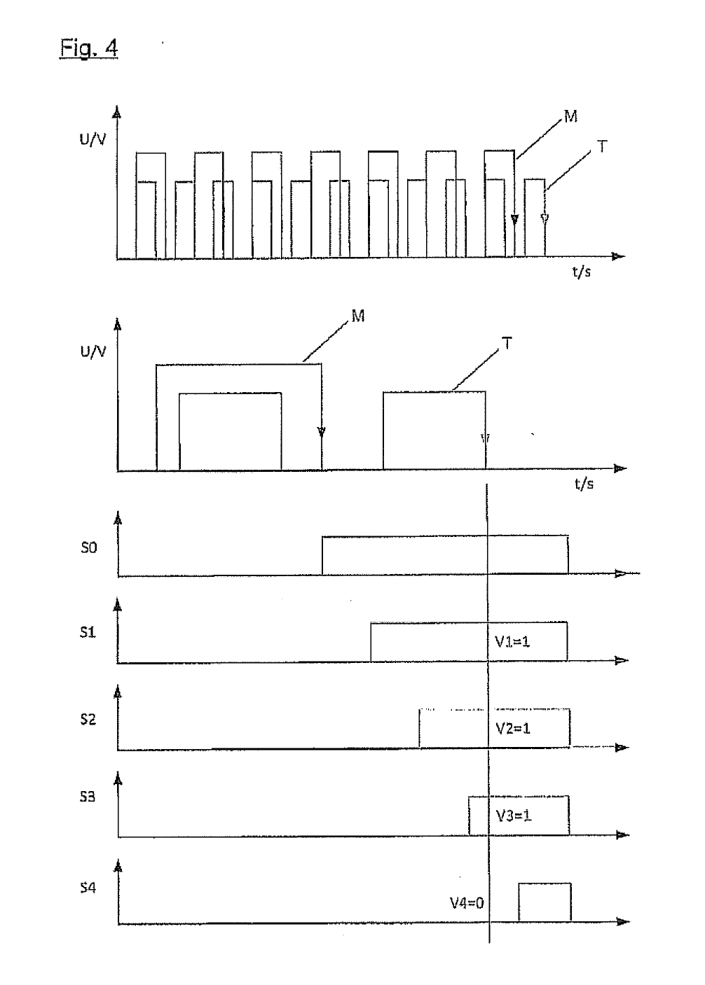

FIG. 1 is a simplified block diagram of a pressure measuring device, in which the measuring device of the invention is used.

FIG. 2 is sample signal curves of the clock signal and the measurement signal.

FIG. 3 is an exemplary sample circuit for measurement refinement.

FIG. 4 is an illustration of sample signal curves of the clock signal, the measurement signal, the delayed measurement signals and the output signals of the comparators in FIG. 3.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down, etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

Various operations may be described as multiple discrete operations in turn, in a manner that may be helpful in understanding embodiments of the present invention; however, the order of description should not be construed to imply that these operations are order dependent, or require a specific order.

FIG. 1 shows a simplified block diagram of a level measuring device, in which a measuring device is provided to determine a measuring capacitance C_{M}. The level measuring device has at least one measuring cell 1, in which the measuring capacitance C_{M} of a capacitor, designed as a plate capacitor for example, changes in dependence on a pressure acting on the measurement cell 1. To normalize the measuring capacitance, a reference capacitance C_{R} can also be provided, by means of which the value output is essentially dimensionless. The measuring capacitance is part of a measuring oscillator 3, which is formed from an oscillatory circuit with the measuring capacitance C_{M}. The measuring oscillator 3 then oscillates depending on the magnitude of the measuring capacitance C_{M} in the measurement frequency f_{M} according to the voltage curves shown at the top of FIG. 2. The sawtooth voltage curves of the measuring oscillator 3 can be converted with the help of a comparator 5, which can be configured either as a Schmidt flip flop, or rectangular signal curves, as shown in the lower part of FIG. 2. Furthermore, a clock signal of a clock oscillator 7 (not shown) is in the bottom part of FIG. 2, oscillating in a scanning frequency f_{A}. As can be seen in FIG. 2, the measurement signal begins to oscillate in synchronization with the clock signal, so that no time delay occurs in this region.

In the sample embodiment shown in FIG. 2, the number of measurement oscillations during which the number of clock oscillations is determined by an edge counter 9 (not shown) is set at 7. This number is chosen dependent on a predetermined measurement time, which is chosen for example based on the requirements for a measurement frequency or a measurement speed or a desired resolution.

The edge counter 9 counts, on the one hand, the number of measurement oscillations, in the present example the number of falling edges of the measurement signal, as well as the number of falling edges of the clock signal. As soon as the 7^{th} falling edge of the measurement signal is detected, the counting of the falling edges of the clock signal is stopped with the edge of the scanning signal immediately following the 7^{th} falling edge of the measurement signal. If, now, an inference is made as to the measurement frequency f_{M} based on knowledge of the scanning frequency of the clock oscillator and with the help of the number of measurement oscillations measured, an error of up to one complete clock period will occur due to the time difference between the last measuring edge and the last clock edge.

In order to achieve an improved measurement value and thereby heighten the resolution of the measurement, a circuit for measurement refinement as shown in FIG. 3 is provided. The circuit for measurement refinement receives as its input signal s₀ the measurement signal 20 is inverted and amplified by an inverting amplifier. In the present sample embodiment, the circuit for measurement refinement has 4 series-connected delay elements 31 to 34. The delay elements 31 to 34 are identical in construction and each of them has an RC element as well as a series-connected non inverting amplifier. In order to make possible a controlled resetting of the delay, the capacitor provided can be bypassed by a switch S.

At the output side, the measurement signal delayed each time relative to the input signal can be picked off from the delay elements 31 to 34 as a comparison signal. The comparison signals s1 to s4 are each taken to a comparator K1 to K4, to which the clock signal is also sent as a second signal. At the output side, a comparison value v1 to v4 can thus be picked off from the comparators K1 to K4, and in the present sample embodiment it is written into a register R. According to the present sample embodiment, each value placed in the register R thus represents ¼ of the clock period.

The signal curves of the measurement signal M, the clock signal P of the inverted and delayed clock signals or comparison signals s1 to s4, and the comparison values v1 to v4, as shown in FIG. 4, once again make clear the principle of the present circuit. Activated by the falling edge of a last measurement oscillation, the measurement signal is taken to the measurement refinement circuit and inverted by the inverting amplifier. The inverted measurement signal is delayed by the delay elements 31 to 34, which are suitably dimensioned, each time by ¼ of the clock period, so that the comparison signals 31 to 34 can be picked off from the delay elements 31 to 34 at the output side. The comparison values v1 to v4 are generated by the comparators K1 to K4, which receive the comparison signals s1 to s4, as well as the clock signal T. As long as a high signal is present at both inputs of the comparators K1 to K4, a high signal will also be put out with v1 to v4 as comparison value. If different signals are present at the inputs of one of the comparators K1 to K4, the comparator will show a low signal. In the present sample embodiment, the input signals at the comparators K1 to K3 are identical due to the inverting and the repeated delaying of the measurement signal M and different at the last comparator K4. Accordingly, the comparison values v1 to v3 are high signals, the comparison value v4 is a low signal. The portion of a clock period represented by the comparison values v1 to v4 is to be subtracted from the measurement value determined by counting of the clock edges, according to the circuit realized in the present sample embodiment.

The measurement refinement in this way detects the time until the next clock edge, which is then to be subtracted from the determined value.

It is advantageous in the embodiment shown that a current requirement for the measurement refinement circuit always occurs only upon a change in pulse edge of the measurement signal M. Measurement errors at the start of the measurement are also avoided by a synchronized activation of measuring and clock oscillators 3.

### LIST of reference symbols

1 measuring cell
3 measuring oscillator
5 Schmidt flip flop
7 clock oscillator (not shown)
9 edge counter (not shown)
31 delay element
32 delay element
33 delay element
34 delay element
C_{M} measuring capacitance
C_{R} reference capacitance
R register
S switch
M measurement signal
T clock signal
f_{M} measurement frequency
f_{A} scanning frequency
V amplifier
R1 resistance
R2 resistance
R3 resistance
R4 resistance
C1 capacitance
C2 capacitance
C3 capacitance
C4 capacitance
K1 comparator
K2 comparator
K3 comparator
K4 comparator
s1 comparison signal
s2 comparison signal
s3 comparison signal
s4 comparison signal
v1 comparison value
v2 comparison value
v3 comparison value
v4 comparison value
s₀ inverted measurement signal

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure cover modifications and variations of this disclosure provided they come within the scope of the appended claims and their equivalents.

What is claimed is:

1. A measuring device, for the determination of a measuring capacitance (C_{M}), comprising:
a clock oscillator operative to oscillate in a scanning frequency (f_{A});
a measuring oscillator operative to oscillate in a measurement frequency in dependence on a measuring capacitance (C_{M}); and
an edge counter operative to count a number of clock oscillations during a given number of measuring oscillations, wherein a circuit is provided for a measurement refinement,
characterized in that the circuit for said measurement refinement is operably started by a measuring edge of a last scanned measuring oscillation and operably stopped by an equally oriented and immediately following edge of a subsequent clock oscillation.

2. A measuring device, according to claim 1, wherein:
the measuring oscillator is started in synchronization with the clock oscillator.

3. A measuring device, according to claim 1, wherein:
the number of measurement pulse edges depends on a predetermined measurement time.

4. A measuring device, according to claim 3, wherein:
the measurement time is 5 ms.

5. A measuring device, according to claim 1, wherein:
the measuring edge is a falling edge.

6. A measuring device, according to claim 1, wherein:
the measuring capacitance (C_{M}) is arranged in an oscillating circuit which constitutes the measuring oscillator.

7. A measuring device, according to claim 1, wherein:
the circuit for measurement refinement has a plurality of series-connected delay elements, to which the measurement signal (M) is supplied and at whose outputs the measurement signal (M) can be picked off that is delayed relative to each other, being the comparison signal (S1).

8. A measuring device, according to claim 7, wherein:
the circuit for measurement refinement has a plurality of comparators, to which the clock signal (T) is supplied on the one hand, and one of the comparison signals on the other.

9. A measuring device, according to claim 1, further comprising:
delay elements, and
said delay elements are operably configured with an identical delay.

10. A method for the measurement of a measuring capacitance, comprising the steps of:
providing a clock oscillator which oscillates with a scanning frequency (f_{A});
providing a measuring oscillator which oscillates with a measuring frequency depending on the measuring capacitance (C_{M});
operably providing an edge counter which counts the number of clock oscillations during a given number of measurement oscillations and wherein the measuring oscillator is started in synchronization with the clock oscillator; and
operably providing a circuit for measurement refinement that is started by a measuring pulse edge of a last scanned measurement oscillation and stopped by an equally oriented edge of an immediately following clock oscillation.

11. A method, according to claim 10, wherein:
the measuring oscillator is started in synchronization with the clock oscillator.

12. A method, according to claim 10, wherein:
the number of measurement oscillations is set dependent on a predetermined measurement time.

13. A method, according to claim 10, wherein:
the measurement signal (M) is repeatedly delayed for the measurement refinement, the delayed measurement signal (M) is compared each time to the clock signal (T) and
the result of this comparison constitutes a portion of the clock signal, which is subtracted from the number of clock oscillations.

14. A method, according to claim 10, wherein:
the circuit for measurement refinement is started by a falling edge of the measurement signal (M) and stopped by an immediately following edge of the clock signal (T).
